(19) United States
(12) Patent Application Publication
(10) Pub. No.: US 2009/0084572 A1
(43) Pub. Date: Apr. 2, 2009

(54) WEATHERPROOF CONNECTOR

(76) Inventor: Kenneth Smith, Seattle, WA (US)

Correspondence Address: JENSEN + PUNTIGAM, P.S., 2033 6th Ave, Suite 1020, SEATTLE, WA, 98121, US

(21) Appl. No.: 11/864,314

(22) Filed: Sep. 28, 2007

(51) Int. Cl. H05K 5/03

(52) U.S. Cl. 174/67; 439/274

(57) ABSTRACT

A weatherproof power inlet box and mating plug wherein the inlet box and mating plug are asymmetrical, positively latched and include more robust elements and a visual indicator of the status of the interconncct. Also included is a thermostat that trips to prevent overheating.

### TECHNICAL FIELD

This invention relates to a weatherproof connector and more particularly to a weatherproof connector system wherein the electrical connector portions when properly connected, interlock to prevent accidental disconnect and visually indicate the status of the connection. Also incorporated is a thermostat to break connection in the event of overheating.

### BACKGROUND OF THE INVENTION

Electrical interconnects have been available and are used principally to supply power to camping vehicles and boats when at dock. The standard electrical interconnect includes projecting prongs which must be aligned with the appropriate receptacle as well as a bayonet type securement device to prevent inadvertent dislodge of the interconnect. These known devices have been known to malfunction because of the continuous motion as on a boat, thereby causing overheating and perhaps fire. Examples of known interconnects are shown in U.S. Pat. No. 5,118,301, granted to Bentivolio Jun. 2, 1992, which serves as an interconnect between matched female connector devices.

U.S. Pat. No. 5,984,719, granted to Flegel Nov. 16, 1999, discloses an auxiliary power supply system but also discloses a standard electrical interconnect.

Likewise, U.S. Pat. No. 6,163,449 granted to Flegel Dec. 19, 2000, utilizes a standard electric interconnect.

### DISCLOSURE OF THE INVENTION

With the above-noted prior art in mind, an electric interconnect is provided wherein the mating of the two parts is predetermined by the configuration of the mating parts, thereby preventing any inadvertent incorrect interconnect.

Further the inventive device includes not only a more robust interconnect element, but also a failsafe securement method in addition to superior sealing from the weather.

The inventive device includes a superior cover and LEDs to indicate the status of the interconnect, i.e., polarity and/or power presence.

It also includes a thermostat to guard against overheating.

### BRIEF DESCRIPTION OF THE DRAWINGS

FIG. 1 is an isometric view of the inventive interconnect device.

FIG. 2 is an isometric view of the interconnect device looking in the opposite direction.

FIG. 3 is a sectional view through the housing for the female element.

FIGS. 4 and 5 are isometric views of the receptacle base and housing therefor.

### BEST MODE FOR CARRYING OUT THE INVENTION

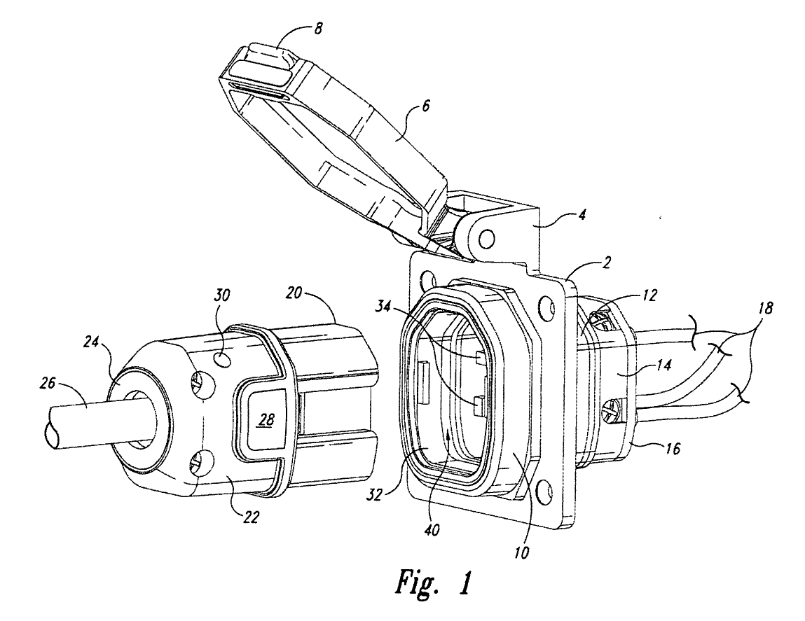

As seen in FIG. 1, the unit fixed to the vehicle or structure includes a mounting plate 2 for securement to a wall including an outwardly extending hinge element 4 to which is mounted a weather cover 6 including a latch 8. Secured to the mounting plate is front flange 10, a rear flange 12, a receptacle base 14 and a receptacle cover 16 through which extend a plurality of wires 18. Likewise seen in this view is the connector receptacle 20, the housing 22, the cap 24 and input wire 26. Likewise seen in this view are a release button 28 and an LED 30.

The connector receptacle 20 is received within the opening 32 surrounded by the front flange 10. Further seen in this view are the male connector elements 34 which are robust.

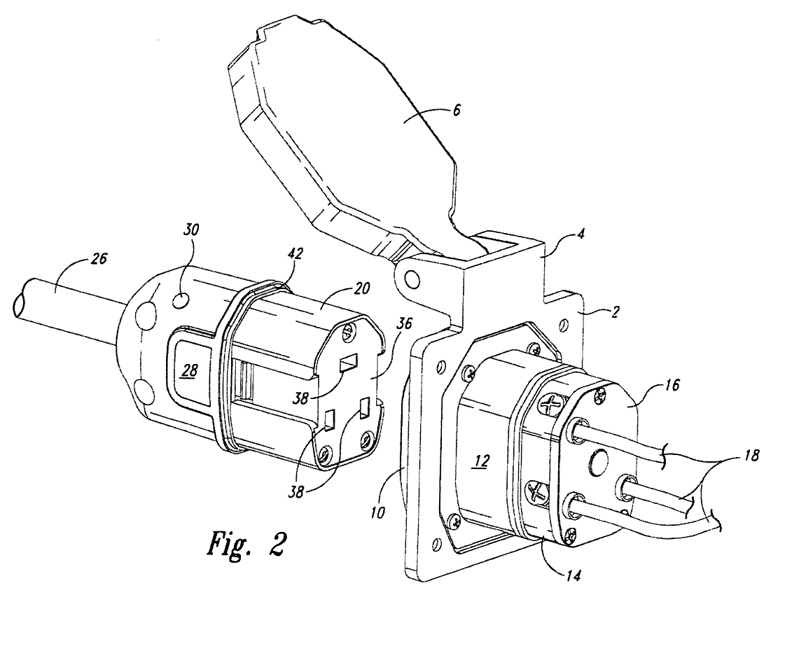

Referring now to FIG. 2, similar parts are identified with the identical number and it is further to be seen that within the connector receptacle 20 is the actual connector 36 having openings 38 to receive male connector members 34.

Further to be seen in FIGS. 1 and 2 are scaling gasket members 40 and 42 which are engaged when the receptacle is in the closed position preventing the influx of any liquid. It is to be noted that opening 32 and receptacle so one asymmetrical preventing an unaligned connection.

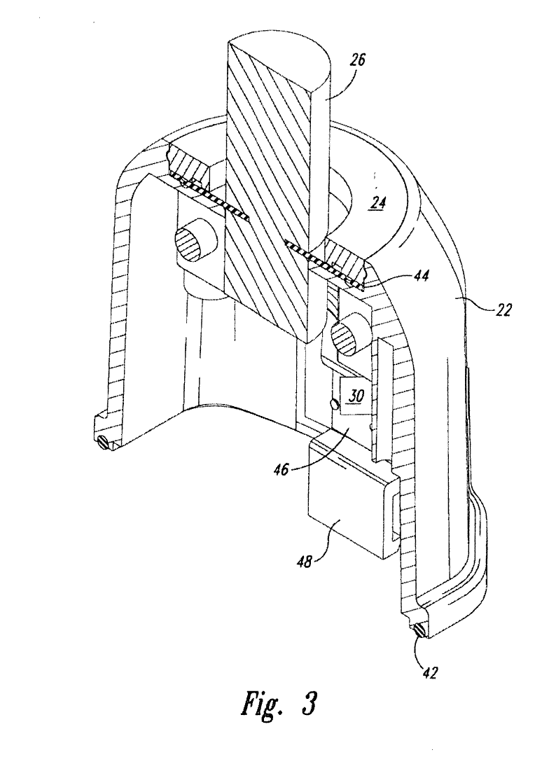

As seen in FIG. 3, in addition to the cap 24 on the housing 22, there is a seal 44 which surrounds the input wire 26. Also seen in this view is a spring 46 which urges the button 28 (not shown) outwardly and the button 28 is integral with the snap fastener element 48.

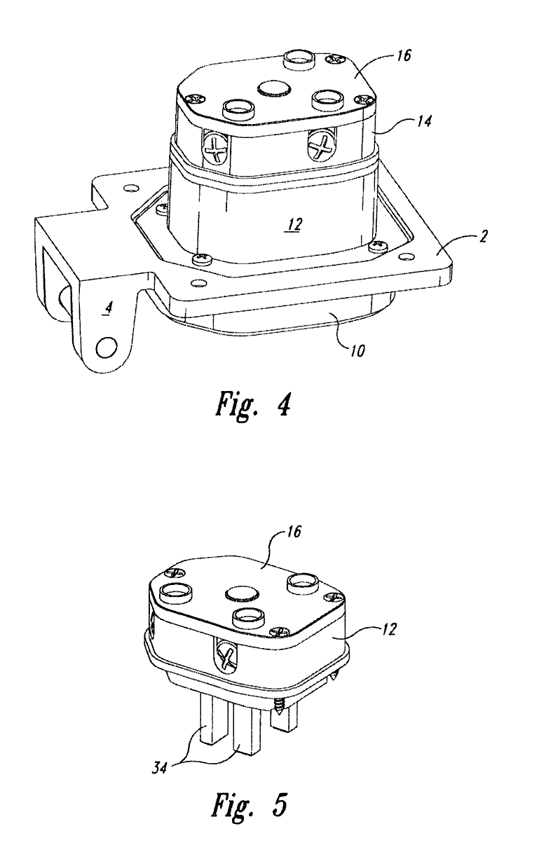

FIGS. 4 and 5 more clearly illustrate the components of the receptacle.

As thus can be seen, the present invention provides a safer, more secure power input for motor vehicles and/or boats.

1. A weatherproof power inlet box and mating plug, comprising:
a wall-mounted female unit, comprising a front flange, a mounting plate including a hinged weather cover and a rear flange surrounding a receptacle base including a cover and further including an outwardly projecting three-prong connector at the receptacle base; and
a removable male unit including a leading end intimately received in the female unit and including a three-prong connector receiver at the front face and a trailing end including a gripping surface and snap fasteners.

2. A weather-proof power inlet, comprising:
first a wall-mounted receptacle and second a selectively removable plug;
said wall-mounted receptacle comprising a mounting plate including a hinged cover, said mounting plate having secured thereto a front flange, a rear flange and a receptacle base, said receptacle base including an outwardly projecting three-prong connector, wherein the receptacle sealingly receives the removable plug; and
said removable plug comprising a forwardly projecting connector receptacle secured in a housing adapted to sealingly mate with the front flange, and including snap fasteners.

3. A power inlet as in claim 2, wherein the removable plug is configured such that it can only be inserted in one orientation.

4. A power inlet as in claim 2, wherein the removable plug includes at least one diode indicating the plug condition.

5. A power inlet box and mating plug as in claim 1, wherein the two elements are latched together.
